(19) United States
(12) Patent Application Publication
(10) Pub. No.: US 2023/0363201 A1
(43) Pub. Date: Nov. 9, 2023

(54) LIGHT-EMITTING ELEMENT AND DISPLAY DEVICE INCLUDING THE SAME

(71) Applicants: Samsung Display Co., Ltd., Yongin-si (KR); KOREA UNIVERSITY Research and Business Foundation, Seoul (KR)

(72) Inventors: YOUNGTAK LEE, Yongin-si (KR); Jun-Young PARK, Seoul (KR); Seungwon LEE, Seoul (KR); Byeong-Kwon JU, Seoul (KR); JAE YOUNG LEE, Yongin-si (KR); Jaewon PARK, Seoul (KR); Young Hyun HWANG, Seoul (KR); Ha HWANG, Seoul (KR)

(73) Assignees: Samsung Display Co., Ltd., Yongin-si (KR); KOREA UNIVERSITY Research and Business Foundation, Seoul (KR)

(21) Appl. No.: 18/125,842

(22) Filed: Mar. 24, 2023

(30) Foreign Application Priority Data
May 4, 2022 (KR) 10-2022-0055671

(51) Int. Cl. H10K 50/80

(52) U.S. Cl. CPC H10K 50/868; H10K 2102/351

(57) ABSTRACT

A light-emitting element includes a first electrode, an insulating layer including a plurality of sub-insulating layers disposed on the first electrode, spaced apart from each other by a distance in the first direction, and having a bar shape extending in the second direction substantially perpendicular to the first direction, a hole transport region disposed on the insulating layer and including a contact portion in contact with the first electrode, and a non-contact portion not contacting the first electrode, a light-emitting layer disposed on the hole transport region and including a light-emitting portion overlapping the contact portion in a plan view, and a diffusion portion overlapping the non-contact portion in a plan view, an electron transport region disposed on the light-emitting layer, and a second electrode disposed on the electron transport region.

### CROSS-REFERENCE TO RELATED APPLICATIONS

This U.S. non-provisional patent application claims priority to and benefits of Korean Patent Application No. 10-2022-0055671 under 35 U.S.C. § 119, filed on May 4, 2022, the entire contents of which are incorporated herein by reference.

### BACKGROUND

The disclosure herein relates to a light-emitting element and a display device including the same, and more particularly, to a light-emitting element including an insulating layer between a light-emitting layer and a hole transport region, and a display device including the same.

Recently, an organic electroluminescence display device, as an image display device, has been actively developed. The organic electroluminescence display device is different from a liquid crystal display device and is a so-called self-luminous display device which realizes display by having an organic compound-containing a light-emitting material emit light in the light-emitting layer through re-combination of holes and electrons injected from a first electrode and a second electrode.

In applying a light-emitting element to a display device, a low driving voltage, high luminous efficiency, and long lifespan are required for the light-emitting element, and the development of a structure for the light-emitting element is required to realize those requirements stably.

### SUMMARY

The disclosure provides a light-emitting element having high luminous efficiency and improved roll-off characteristics at a high luminance, and a display device including the same.

An embodiment of the disclosure provides a light-emitting element including a first electrode; an insulating layer including a plurality of sub-insulating layers disposed on the first electrode, spaced apart from each other by a distance in a first direction, and having a bar shape extending in a second direction substantially perpendicular to the first direction; a hole transport region disposed on the insulating layer and including a contact portion in contact with the first electrode; and a non-contact portion not contacting the first electrode; a light-emitting layer disposed on the hole transport region and including a light-emitting portion overlapping the contact portion in a plan view, and a diffusion portion overlapping the non-contact portion in a plan view; an electron transport region disposed on the light-emitting layer; and a second electrode disposed on the electron transport region.

In an embodiment, the light-emitting layer may emit light in a range of about 450 nm to about 520 nm.

In an embodiment, a thickness of each of the sub-insulating layers may be in a range of about 30 nm to about 60 nm.

In an embodiment, a width in the first direction of each of the plurality of sub-insulating layers may be in a range of about 150 nm to about 200 nm.

In an embodiment, the electron transport region may include a plurality of first portions overlapping the plurality of sub-insulating layers in a plan view, and a plurality of second portions non-overlapping the sub-insulating layers in a plan view, wherein each of the plurality of first portions may have a convex shape in the direction of the second electrode, and each of the plurality of second portions may have a convex shape in the direction of the first electrode.

In an embodiment, a sum of the separation distance between adjacent sub-insulating layers of the plurality of sub-insulating layers and a width in the first direction of one of the adjacent sub-insulating layers may be in a range of about 500 nm to about 600 nm.

In an embodiment, each of the plurality of sub-insulating layer may include a photosensitizer for laser interference lithography.

In an embodiment, the insulating layer may have a visible light transmittance of about 85% or more.

In an embodiment, the light-emitting layer may be a thermally-activated delayed fluorescent light-emitting layer, a hyper-fluorescent light-emitting layer, or a phosphorescent light-emitting layer.

In an embodiment, excitons may be formed in the light-emitting layer, and a density of the excitons in the light-emitting portion may be greater than a density of the excitons in the diffusion portion.

In an embodiment of the disclosure, a display device includes first to third light-emitting regions; a circuit layer disposed on a base substrate; and a light-emitting layer including a pixel defining film disposed on the circuit layer and having an opening, and first to third light-emitting elements, wherein each of the first to third light-emitting elements include a first electrode exposed by the pixel defining film; an insulating layer including a plurality of sub-insulating layers disposed on the first electrode, spaced apart from each other by a distance in a first direction in the opening, and having a bar shape extending in a second direction substantially perpendicular to the first direction in a plan view; a hole transport region disposed on the insulating layer and including a contact portion in contact with the first electrode, and a non-contact portion not contacting the first electrode; a light-emitting layer disposed on the hole transport region and divided by the pixel defining film; an electron transport region disposed on the light-emitting layer; and a second electrode disposed on the electron transport region.

In an embodiment, the light-emitting layer may be a thermally activated delayed fluorescent light-emitting layer, a hyper-fluorescent light-emitting layer, or a phosphorescent light-emitting layer.

In an embodiment, the light-emitting layer may include a first light-emitting layer disposed to correspond to the first light-emitting region, a second light-emitting layer disposed to correspond to the second light-emitting region, and a third light-emitting layer disposed to correspond to the third light-emitting region, and the first to third light-emitting layers may respectively emit light of different wavelength ranges.

In an embodiment, the electron transport region may include a plurality of first portions overlapping the plurality of sub-insulating layers in a plan view, and a plurality of second portions non-overlapping the sub-insulating layers in a plan view, wherein each of the first portions may have a convex shape in a direction of the second electrode, and each of the second portions may have a convex shape in a direction of the first electrode.

In an embodiment, in at least one of the first to third light-emitting elements, a thickness of each of the plurality of sub-insulating layers may be in a range of about 30 nm to about 60 nm.

In an embodiment, a sum of a separation distance between adjacent sub-insulating layers of the plurality of sub-insulating layers and a width in the first direction of one of the adjacent sub-insulating layers may be about 500 nm to about 600 nm.

In an embodiment, in at least one of the first to third light-emitting elements, the width in the first direction of each of the sub-insulating layers may be in a range of about 150 nm to about 200 nm.

In an embodiment, the insulating layer may have a visible light transmittance of about 85% or more.

In an embodiment, each of the plurality of sub-insulating layer may include a photosensitizer for laser interference lithography.

In an embodiment, the light-emitting layer may include a light-emitting portion overlapping the contact portion in a plan view, and a diffusion portion overlapping the non-contact portion in a plan view, wherein excitons may be formed in the light-emitting layer, and a density of the excitons in the light-emitting portion may be greater than a density of the excitons in the diffusion portion.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain principles of the disclosure. In the drawings:

FIG. 1 is a schematic perspective view of a display device according to an embodiment of the disclosure;

FIG. 2 is a schematic cross-sectional view of the display device according to an embodiment of the disclosure;

FIG. 3 is a schematic plan view of a display module according to an embodiment of the disclosure;

FIG. 4 is a schematic cross-sectional view of the display module according to an embodiment of the disclosure;

FIG. 5 is a schematic plan view of a portion of the display module according to an embodiment of the disclosure;

FIG. 6 is a schematic cross-sectional view schematically illustrating a light-emitting element according to an embodiment of the disclosure;

FIG. 7 is a schematic perspective view schematically illustrating a portion of the light-emitting element according to an embodiment of the disclosure;

FIG. 8 is a schematic perspective view illustrating a portion of a light-emitting element according to a comparative embodiment of the disclosure;

FIG. 9 is a graph showing a simulation result of a relationship between a light-emitting wavelength, a light extraction enhancement factor, and a pitch of sub-insulating layers in a light-emitting element according to an embodiment of the disclosure;

FIG. 10A is a graph showing changes in current density and luminance in accordance with the voltages of a light-emitting element according to an embodiment of the disclosure and light-emitting elements according to comparative embodiments of the disclosure;

FIG. 10B is a graph showing changes in external quantum efficiency in accordance with the luminances of a light-emitting element according to an embodiment of the disclosure and light-emitting elements according to comparative embodiments of the disclosure;

FIG. 10C is a graph showing changes in light extraction enhancement factor in accordance with the widths of a light-emitting element according to an embodiment of the disclosure;

FIG. 11A is a graph showing changes in current density and luminance in accordance with the voltages of a light-emitting element according to an embodiment of the disclosure and light-emitting elements according to comparative embodiments of the disclosure;

FIG. 11B is a graph showing changes in external quantum efficiency in accordance with the luminances of a light-emitting element according to an embodiment of the disclosure and light-emitting elements according to comparative embodiments of the disclosure;

FIG. 11C is a graph showing changes in light extraction enhancement factor in accordance with the thicknesses of a light-emitting element according to an embodiment of the disclosure;

FIG. 12A is a graph showing changes in external quantum efficiency in accordance with the luminances of a light-emitting element according to an embodiment of the disclosure and light-emitting elements according to a comparative embodiment of the disclosure; and

FIG. 12B is a graph showing changes in external quantum efficiency in accordance with the luminances of a light-emitting element according to an embodiment of the disclosure and light-emitting elements according to a comparative embodiment of the disclosure.

### DETAILED DESCRIPTION OF THE EMBODIMENTS

In the disclosure, various modifications can be made, various forms can be used, and specific embodiments will be illustrated in the drawings and described in detail in the text. However, this is not intended to limit the disclosure to a specific form disclosed, and it will be understood that all changes, equivalents, and substitutes which fall in the spirit and technical scope of the disclosure should be included.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Meanwhile, in the disclosure, “directly disposed” may mean that there is no layer, film, region, plate, etc. added between a portion such as a layer, film, region, or plate and another portion. For example, “direct disposed” may mean placing two layers or two members without using an additional member such as an adhesive member therebetween.

The same reference numerals or symbols refer to the same elements. In addition, in the drawings, the thicknesses, ratios, and dimensions of elements may be exaggerated for effective description of technical content.

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Terms such as first and second may be used to describe various elements, but the elements should not be limited by the terms. These terms are only used for the purpose of distinguishing one element from other elements. For example, without departing from the scope of the disclosure, a first element may be referred to as a second element, and similarly, a second element may be referred to as a first element. Singular expressions may include plural expressions unless the context clearly indicates otherwise.

In addition, terms such as “below”, “lower”, “above”, and “upper” are used to describe the relationship between elements shown in the drawings. The terms are relative concepts and are described based on the directions indicated in the drawings.

Terms such as “include” or “have” are intended to designate the presence of a feature, number, step, action, element, part, or combination thereof described in the specification, and it should be understood that it does not preclude the possibility of presence or addition of one or more other features, numbers, steps, operations, elements, parts, or combinations thereof.

Unless otherwise defined or implied herein, all terms (including technical and scientific terms) used in this specification have the same meaning as commonly understood by one of ordinary skill in the art to which this disclosure belongs. In addition, it will be further understood that terms, such as those defined in commonly used dictionaries, should be interpreted as having a meaning that is consistent with their meaning in the context of the related technology, and should not be interpreted in an idealized or overly formal sense unless expressly so defined herein.

Hereinafter, a display device according to an embodiment of the disclosure will be described with reference to the accompanying drawings.

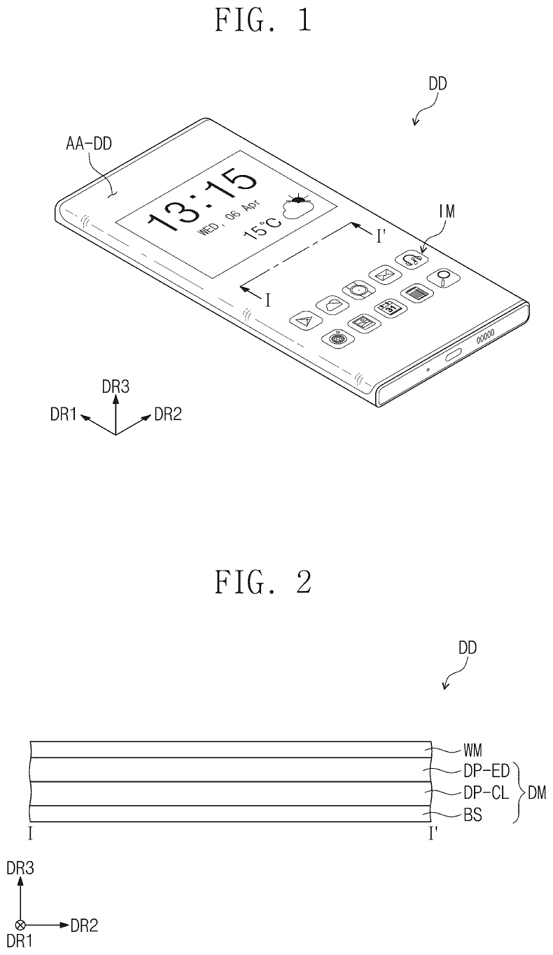

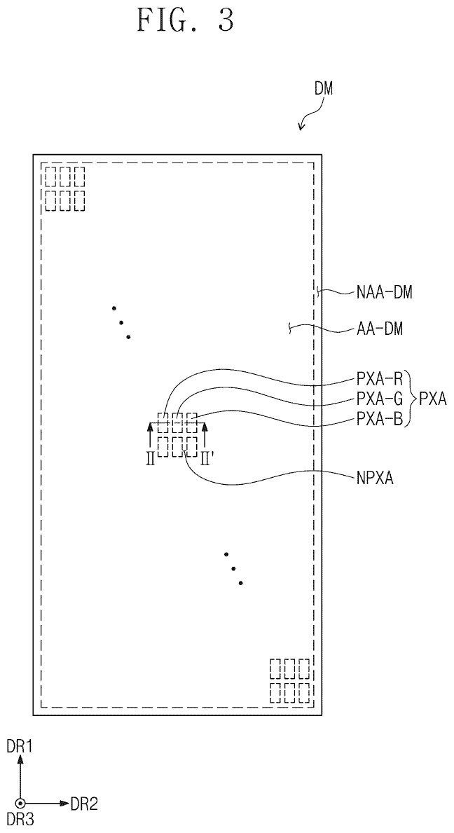

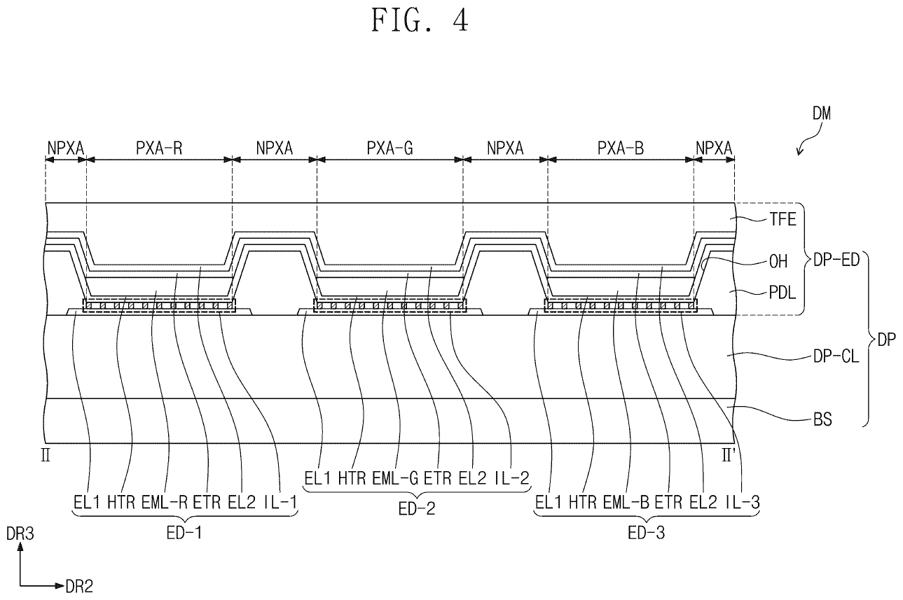

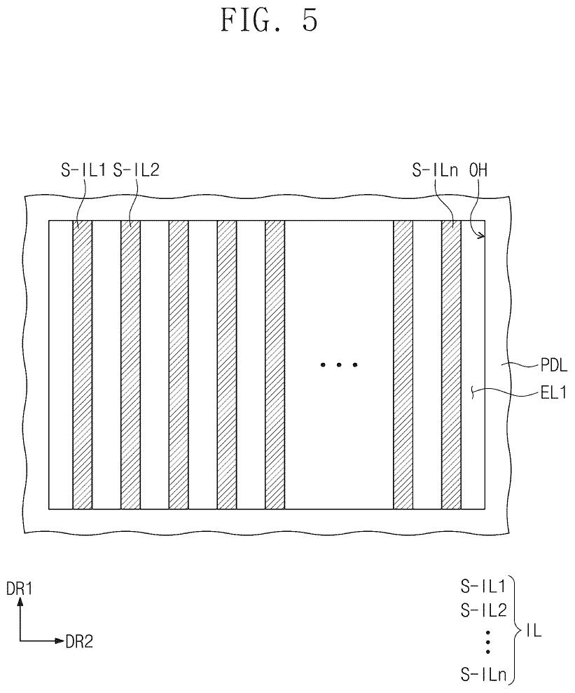

FIG. 1 is a schematic perspective view of a display device according to an embodiment of the disclosure. FIG. 2 is a schematic cross-sectional view of the display device according to an embodiment of the disclosure. FIG. 2 is a schematic cross-sectional view corresponding to line I-I′ of FIG. 1. FIG. 3 is a schematic plan view of a display module according to an embodiment of the disclosure. FIG. 4 is a schematic cross-sectional view of the display module according to an embodiment of the disclosure. FIG. 4 illustrates a cross section corresponding to line II-IT of FIG. 3. FIG. 5 is a schematic plan view of a portion of the display module according to an embodiment of the disclosure.

Referring to FIGS. 1 and 2, a display device DD according to an embodiment of the disclosure may be activated according to an electrical signal. For example, the display device DD may be a mobile phone, a tablet personal computer (PC), a car navigation system, a game machine, or a wearable device, but is not limited thereto. FIG. 1 illustrates that the display device DD is a mobile phone.

The display device DD may display an image IM through an active region AA-DD. The active region AA-DD may include a plane defined by a first direction axis DR1 and a second direction axis DR2. The active region AA-DD may further include a curved surface bent from at least one side of the plane defined by the first direction axis DR1 and the second direction axis DR2. As illustrated in FIG. 1, the display device DD according to an embodiment of the disclosure is illustrated to include two curved surfaces respectively bent from sides of the plane defined by the first direction axis DR1 and the second direction axis DR2. However, the shape of the active region AA-DD is not limited thereto. For example, the active region AA-DD may include only the plane, or the active region AA-DD may include at least two or more, for example, four curved surfaces bent from the four sides of the plane, respectively.

FIG. 1 and following drawings illustrate first to third direction axes DR1 to DR3, and directions indicated by the first to third direction axes DR1, DR2 and DR3 described in this specification are relative concepts and may be converted into other directions. The directions indicated by the first to third direction axes DR1, DR2, and DR3 may be described as first to third directions which the same reference numerals may be used for.

In this specification, the first direction axis DR1 and the second direction axis DR2 are perpendicular to each other, and the third direction axis DR3 may be a direction normal to the plane defined by the first direction axis DR1 and the second direction axis DR2.

The display device DD according to an embodiment of the disclosure may include a display module DM and a window WM disposed on the display module DM. The display module DM may include a base layer BS, a circuit layer DP-CL disposed on the base layer BS, and a light-emitting element layer DP-ED disposed on the circuit layer DP-CL.

The base layer BS may be a member configured to provide a base surface on which the light-emitting element layer DP-ED is disposed. The base layer BS may be a glass substrate, a metal substrate, a polymer substrate, or the like. However, the embodiment of the disclosure is not limited thereto, and the base layer BS may be an inorganic layer, a functional layer, or a composite layer (or composite material layer).

The base layer BS may have a multi-layered structure. For example, the base layer BS may have a three-layer structure of a polymer resin layer, an adhesive layer, and a polymer resin layer. In particular, the polymer resin layer may contain a polyimide-based resin. The polymer resin layer may include at least one of an acryl-based resin, a methacryl-based resin, a polyisoprene-based resin, a vinyl-based resin, an epoxy-based resin, a urethane-based resin, a cellulose-based resin, a siloxane-based resin, a polyamide-based resin, a novolak-type phenol-based resin, or a perylene-based resin. In this specification, an “X-based” resin means to include a functional group of “X”.

In an embodiment of the disclosure, the circuit layer DP-CL may be disposed on the base layer BS, and the circuit layer DP-CL may include transistors (not illustrated). Each of the transistors (not illustrated) may include a control electrode, an input electrode, and an output electrode. For example, the circuit layer DP-CL may include a switching transistor and a driving transistor which are configured to drive light-emitting elements ED-1, ED-2, and ED-3 of the light-emitting element layer DP-ED.

The light-emitting element layer DP-ED may be disposed on the circuit layer DP-CL. The light-emitting element layer DP-ED may include a pixel defining film PDL, the light-emitting elements ED-1, ED-2, and ED-3 disposed between portions of the pixel defining film PDL, and an encapsulation layer TFE disposed on the light-emitting elements ED-1, ED-2, and ED-3. The light-emitting element layer DP-ED may include an organic light-emitting element or a quantum dot light-emitting element as the light-emitting elements ED-1, ED-2, and ED-3.

The display device DD according to an embodiment of the disclosure may further include another layer between the light-emitting element layer DP-ED and the window WM. For example, the display device DD according to an embodiment of the disclosure may further include at least one of optical functional layers such as a light path control layer configured to change a light path between the light-emitting element layer DP-ED and the window WM or a reflection prevention layer configured to reduce the reflectance of external light incident from the outside.

The window WM may be disposed on the display module DM. The window WM may correspond to the uppermost layer of the display device DD. The window WM may be a tempered glass substrate that has been tempered. Since the window WM includes a reinforced surface, the display module DM may be reliably protected from an external impact. The window WM according to an embodiment of the disclosure may further include a printed layer (not illustrated) disposed on an inner or outer edge thereof. For example, the printed layer (not illustrated) may be a portion provided to correspond to a peripheral region NAA-DM. An adhesive member (not illustrated) may be further disposed between the window WM and the display module DM. The adhesive member (not illustrated) may include an optically clear adhesive layer.

The display module DM may include an active region AA-DM and a peripheral region NAA-DM adjacent to the periphery of the active region AA-DM. The active region AA-DM may be activated according to an electrical signal. The peripheral region NAA-DM may surround the active region AA-DM. A driving circuit or a driving line configured to drive the active region AA-DM, various signal lines or pads configured to provide an electrical signal to the active region AA-DM, electronic elements, or the like may be disposed in the peripheral region NAA-DM.

Referring to FIGS. 3 to 5, the display device DD according to an embodiment of the disclosure may include a display module DM including light-emitting regions PXA.

The light-emitting regions PXA may include a first light-emitting region PXA-R, a second light-emitting region PXA-G, and a third light-emitting region PXA-B which respectively correspond to the light-emitting elements ED-1, ED-2, and ED-3. The first to third light-emitting regions PXA-R, PXA-G, and PXA-B may be regions in which light generated from each of the light-emitting elements ED-1, ED-2, and ED-3 is emitted. The first to third light-emitting regions PXA-R, PXA-G, and PXA-B may correspond to pixel openings OH in each of the light-emitting elements ED-1, ED-2, and ED-3.

In a plan view, the first to third light-emitting regions PXA-R, PXA-G, and PXA-B may not overlap each other and may be separated from each other. For example, a non-light-emitting region NPXA may be disposed between adjacent light-emitting regions PXA-R, PXA-G, and PXA-B.

Each of the light-emitting regions PXA-R, PXA-G, and PXA-B may be divided by the pixel defining film PDL. The non-light-emitting regions NPXA may be regions between neighboring light-emitting regions PXA-R, PXA-G, and PXA-B and correspond to the pixel defining film PDL. In this specification, each of the light-emitting regions PXA-R, PXA-G, and PXA-B may correspond to a pixel. The pixel defining film PDL may separate the light-emitting elements ED-1, ED-2, and ED-3 from each other. The light-emitting layers EML-R, EML-G, and EML-B of the light-emitting elements ED-1, ED-2, and ED-3 may be disposed in the openings OH defined in the pixel defining film PDL so that they may be separated from each other. Insulating layers IL-1, IL-2, and IL-3 of the light-emitting elements ED-1, ED-2, and ED-3 may be disposed in the openings OH defined in the pixel defining film PDL so that they may be separated from each other.

The light-emitting regions PXA-R, PXA-G, and PXA-B may be divided into groups according to the color of light generated from the light-emitting elements ED-1, ED-2, and ED-3. Three light-emitting regions PXA-R, PXA-G, and PXA-B configured to emit red light, green light, and blue light are disposed in the display device DD according to an embodiment of the disclosure, which is illustrated in FIGS. 1 and 2 as an example. For example, the display device DD according to an embodiment of the disclosure may include a red light-emitting region PXA-R, a green light-emitting region PXA-G, and a blue light-emitting region PXA-B which are separated from each other.

In the display device DD according to an embodiment of the disclosure, the light-emitting elements ED-1, ED-2, and ED-3 may emit light of different wavelength ranges. For example, in an embodiment of the disclosure, the display device DD may include a first light-emitting element ED-1 configured to emit red light, a second light-emitting element ED-2 configured to emit green light, and a third light-emitting element ED-3 configured to emit blue light. For example, the red light-emitting region PXA-R, the green light-emitting region PXA-G, and the blue light-emitting region PXA-B of the display device DD may respectively correspond to the first light-emitting element ED-1, the second light-emitting element ED-2, and the third light-emitting element ED-3.

The light-emitting regions PXA-R, PXA-G, and PXA-B in the display device DD according to an embodiment of the disclosure may be arranged in a stripe shape. Referring to FIG. 3, each of red light-emitting regions PXA-R, green light-emitting regions PXA-G, and blue light-emitting regions PXA-B may be aligned in the second direction axis DR2. The red light-emitting regions PXA-R, the green light-emitting regions PXA-G, and the blue light-emitting regions PXA-B may be alternately arranged in the order named in the first direction axis DR1.

Although FIG. 3 illustrates that the areas of the light-emitting regions PXA-R, PXA-G, and PXA-B are all similar to each other, the embodiment of the disclosure is not limited thereto, and the areas of the light-emitting regions PXA-R PXA-G and PXA-B may be different from each other according to the wavelength range of emitted light. The areas of the light-emitting regions PXA-R, PXA-G, and PXA-B may mean areas when viewed on a plane defined by the first direction axis DR1 and the second direction axis DR2.

The arrangement shape of the light-emitting regions PXA-R, PXA-G, and PXA-B is not limited to what is illustrated in FIG. 1, and the order in which the red light-emitting region PXA-R, the green light-emitting region PXA-G, and the blue light-emitting region PXA-B are arranged may be provided in various combinations according to the characteristics of display quality required for the display device DD. For example, the light-emitting regions PXA-R, PXA-G, and PXA-B may have a PENTILE™ arrangement shape or a Diamond Pixel™ arrangement shape.

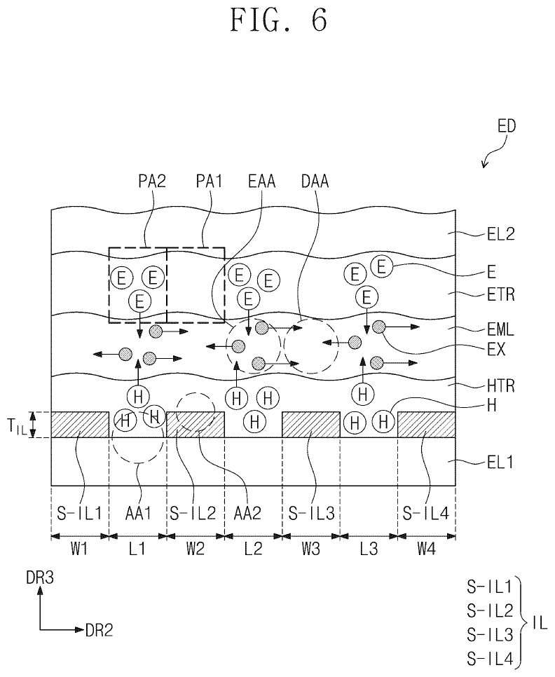

Each of the light-emitting elements ED-1, ED-2, and ED-3 may have the structure of a light-emitting element ED according to an embodiment of the disclosure, which will be described below with reference to FIG. 6. Each of the light-emitting elements ED-1, ED-2, and ED-3 may include a first electrode EL1, insulating layers IL-1, IL-2, and IL-3, a hole transport region HTR, light-emitting layers EML-R, EML-G, and EML-B, an electron transport region ETR, and a second electrode EL2.

FIG. 4 illustrates an embodiment of the disclosure in which the insulating layers IL-1, IL-2, and IL-3 and the light-emitting layers EML-R, EML-G, and EML-B of the light-emitting elements ED-1, ED-2, and ED-3 are disposed in the openings OH defined in the pixel defining film PDL, and the hole transport region HTR, the electron transport region ETR, and the second electrode EL2 are provided as common layers in the entire light-emitting elements ED-1, ED-2, and ED-3. However, the embodiment of the disclosure is not limited thereto, and unlike what is illustrated in FIG. 2, in an embodiment of the disclosure, the hole transport region HTR and the electron transport region ETR may be provided by being patterned inside the opening OH defined in the pixel defining film PDL. For example, in an embodiment of the disclosure, the hole transport region HTR, the light-emitting layers EML-R, EML-G, EML-B, the electron transport region ETR, and the like of the light-emitting elements ED-1, ED-2, and ED-3 may be provided by being patterned by an inkjet printing method.

The encapsulation layer TFE may cover the light-emitting elements ED-1, ED-2, and ED-3. The encapsulation layer TFE may seal the light-emitting element layer DP-ED. The encapsulation layer TFE may be a thin-film encapsulation layer. The encapsulation layer TFE may be a single layer or include layers stacked on top of each other. The encapsulation layer TFE may include at least one insulating layer. The encapsulation layer TFE according to an embodiment of the disclosure may include at least one inorganic layer (hereinafter referred to as an inorganic encapsulation layer). The encapsulation layer TFE according to an embodiment of the disclosure may include at least one organic layer (hereinafter referred to as an organic encapsulation layer) and at least one inorganic encapsulation layer.

The inorganic encapsulation layer may protect the light-emitting element layer DP-ED from moisture or oxygen, and the organic encapsulation layer may protect the light-emitting element layer DP-ED from foreign substances such as dust particles. The inorganic encapsulation layer may contain silicon nitride, silicon oxynitride, silicon oxide, titanium oxide, aluminum oxide, or the like, but is not particularly limited thereto. The organic encapsulation layer may contain an acryl-based compound, an epoxy-based compound, or the like. The organic encapsulation layer may contain a photopolymerizable organic material and is not particularly limited thereto.

The encapsulation layer TFE may be disposed on the second electrode EL2 and may be disposed to fill the opening OH.

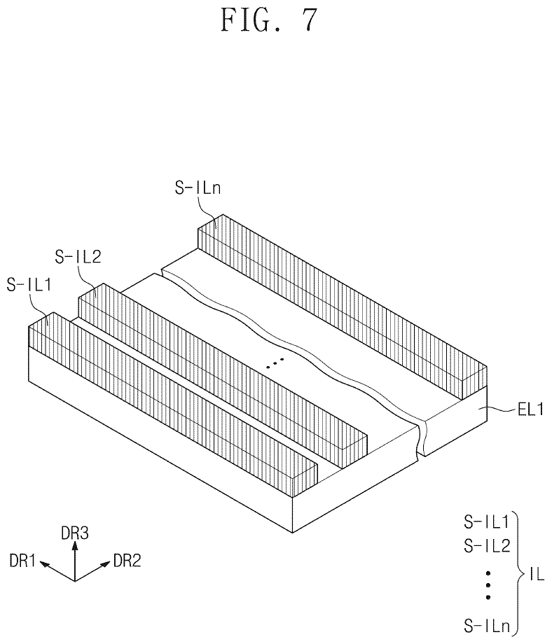

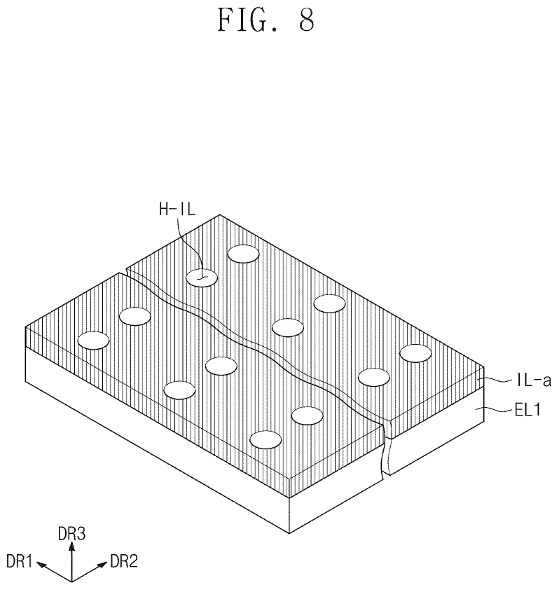

The insulating layers IL-1, IL-2, and IL-3 of the light-emitting elements ED-1, ED-2, and ED-3 may include sub-insulating layers S-IL1 to S-ILn disposed to be spaced apart from each other in the second direction DR2 in a plan view. The sub-insulating layers S-IL1 to S-ILn may be disposed on the first electrode EL1 in the openings OH defined in the pixel defining film PDL. Each of the sub-insulating layers S-IL1 to S-ILn may have a shape extending in the first direction DR1. The insulating layers IL-1, IL-2, and IL-3 may control a contact area between the first electrode EL1 and the hole transport region HTR. The sub-insulating layers S-IL1 to S-ILn will be described in more detail with reference to FIGS. 6 and 7.

FIG. 6 is a cross-sectional view schematically illustrating a light-emitting element according to an embodiment of the disclosure. FIG. 7 is a perspective view schematically illustrating a portion of the light-emitting element according to an embodiment of the disclosure.

Referring to FIGS. 6 and 7, the light-emitting element ED according to an embodiment of the disclosure may include a first electrode EL1, an insulating layer IL, a hole transport region HTR, a light-emitting layer EML, an electron transport region ETR, and a second electrode EL2 which are sequentially stacked each other.

The first electrode EL1 has conductivity. The first electrode EL1 may be formed of a metal material, a metal alloy, or a conductive compound. The first electrode EL1 may be an anode or a cathode. However, the embodiment of the disclosure is not limited thereto. The first electrode EL1 may be a pixel electrode. The first electrode EL1 may be a transmissive electrode, a transflective electrode, or a reflective electrode. The first electrode EL1 may contain at least one selected from the group consisting of Ag, Mg, Cu, Al, Pt, Pd, Au, Ni, Nd, Ir, Cr, Li, Ca, LiF, Mo, Ti, W, In, Sn, and Zn, a compound of two or more selected therefrom, a mixture of two or more selected therefrom, or an oxide thereof.

The insulating layer IL may have insulating properties. The insulating layer IL may include N sub-insulating layers S-IL1 to S-ILn disposed to be spaced apart from each other in the second direction DR2. Each of the sub-insulating layers S-IL1 to S-ILn may have a bar shape extending in the first direction DR1. For the convenience of explanation, FIG. 6 illustrates four sub-insulating layers S-IL1, S-IL2, S-IL3, and S-IL4, but this is only an example and the number of the sub-insulating layers S-IL1, S-IL2, S-IL3, and S-IL4 is not limited thereto.

The sub-insulating layers S-IL1, S-IL2, S-IL3, and S-IL4 may be disposed to be spaced apart from each other by a distance (e.g., a predetermined or selectable distance) in the second direction DR2. The insulating layer IL may expose a portion of the first electrode ELL The first sub-insulating layer S-IL1 and the second sub-insulating layer S-IL2 may be disposed to be spaced apart from each other by a first distance L1, the second sub-insulating layer S-IL2 and the third sub-insulating layer S-IL3 may be disposed to be spaced apart from each other by a second distance L2, and the third sub-insulating layer S-IL3 and the fourth sub-insulating layer S-IL4 may be disposed to be spaced apart from each other by a third distance L3. The separation distances L1, L2, and L3 of the sub-insulating layers S-IL1, S-IL2, S-IL3, and S-IL4 may all be the same, or at least one thereof may be different from the others.

The sub-insulating layers S-IL1, S-IL2, S-IL3, and S-IL4 disposed to be spaced apart from each other may affect the occurrence of a step difference on the surfaces of the hole transport region HTR, the light-emitting layer EML, the electron transport region ETR, and the second electrode EL2 which are disposed on the insulating layer IL. For example, in a cross-sectional view, the electron transport region ETR may include first portions PA1 respectively overlapping the sub-insulating layers S-IL1, S-IL2, S-IL3, and S-IL4, and second portions PA2 non-overlapping the sub-insulating layers S-IL1, S-IL2, S-IL3, and S-IL4. The first portions PA1 and the second portions PA2 may have a height difference in a thickness direction. The first portions PA1 may have a convex shape in the direction of the second electrode EL2, and the second portions PA2 may have a convex shape in the direction of the first electrode ELL Accordingly, the electron transport region ETR may have a curved shape. The descriptions of the first portions PA1 and the second portions PA2 of the electron transport region ETR may be equally applied to a contact portion AA1 and a non-contact portion AA2 of the hole transport region HTR, and a light-emitting portion EAA and a diffusion portion DAA of the light-emitting layer EML. The descriptions of the first portions PA1 and the second portions PA2 may be equally applied to a portion in which the second electrode EL2 overlaps the first portions PA1 and a portion in which the second electrode EL2 overlaps the second portions PA2, respectively.

In general, at the interface between an organic layer and a metal layer, there is a problem in which energy loss increases due to surface plasmon-polaritons (SPP). Since the light-emitting element ED according to an embodiment of the disclosure includes the sub-insulating layers S-IL1, S-IL2, S-IL3, and S-IL4, and the surface of the electron transport region ETR has a curved shape due to a step difference formed by the sub-insulating layers S-IL1, S-IL2, S-IL3, and S-IL4, a diffraction grating may be formed at the interface between the electron transport region ETR, which is an organic layer, and the second electrode EL2, which is a metal layer. Accordingly, as a surface plasmon-polariton phenomenon may be reduced at the interface between the electron transport region ETR as an organic layer, and the second electrode EL2 as a metal layer, the efficiency of the light-emitting element ED may be improved. In case that the separation distances L1, L2, and L3 of adjacent sub-insulating layers S-IL1, S-IL2, S-IL3, and S-IL4 are adjusted, the luminous efficiency of light in a specific wavelength range, which is emitted from the light-emitting element ED, may be increased. For example, in case that the separation distances L1, L2, and L3 of the sub-insulating layers S-IL1, S-IL2, S-IL3, and S-IL4 are adjusted to be in a range of about 300 nm to about 400 nm, the light-emitting element ED configured to emit light having a wavelength range of about 450 nm to about 520 nm may exhibit excellent (or desirable) luminous efficiency.

The widths W1, W2, W3, and W4 of the sub-insulating layers S-IL1, S-IL2, S-IL3, and S-IL4 in the second direction DR2 may be in a range of about 150 nm to about 200 nm. The widths W1, W2, W3, and W4 of the sub-insulating layers S-IL1, S-IL2, S-IL3, and S-IL4 in the second direction DR2 may all be the same, or at least one thereof may be different from the others. In case that the widths W1, W2, W3, and W4 of the sub-insulating layers S-IL1, S-IL2, S-IL3, and S-IL4 in the second direction DR2 are less than about 150 nm or more than about 200 nm, the luminous efficiency of the light-emitting element ED may be reduced.

The sum of the separation distances L1, L2, and L3 of adjacent sub-insulating layers S-IL1, S-IL2, S-IL3, and S-IL4 and the widths W1, W2, W3, and W4 of the sub-insulating layers S-IL1, S-IL2, S-IL3, the S-IL4 in the second direction DR2 may be in a range of about 500 nm to about 600 nm. The sum of the separation distances L1, L2, and L3 of the adjacent sub-insulating layers S-IL1, S-IL2, S-IL3, and S-IL4 and the widths W1, W2, W3, and W4 of the sub-insulating layers S-IL1, S-IL2, S-IL3, and S-IL4 in the second direction DR2 is defined as a pitch of the sub-insulating layers S-IL1, S-IL2, S-IL3, and S-IL4. The pitch of the sub-insulating layers S-IL1, S-IL2, S-IL3, and S-IL4 may affect the luminous efficiency of light emitted from the light-emitting element ED. In case that the wavelength range of the light emitted from the light-emitting element ED is blue light having a wavelength range of about 450 nm to about 520 nm, in case that the pitch of the sub-insulating layers S-IL1, S-IL2, S-IL3, and S-IL4 is adjusted to be in a range of about 500 nm to about 600 nm, the light-emitting element ED may have excellent luminous efficiency.

The thickness T_{IL} of the sub-insulating layers S-IL1, S-IL2, S-IL3, and S-IL4 may be in a range of about 30 nm to about 60 nm. In case that the thickness T_{IL} of the sub-insulating layers S-IL1, S-IL2, S-IL3, and S-IL4 is less than 30 nm, the step difference (or height or thickness difference) in a curved shape obtained by the sub-insulating layers S-IL1, S-IL2, S-IL3, and S-IL4 is not large. Therefore, a diffraction grating is not formed at the interface between the electron transport region ETR and the second electrode EL2, and it is difficult to reduce a surface plasmon-polariton phenomenon. In case that the thickness T_{IL} of the sub-insulating layers S-IL1, S-IL2, S-IL3, and S-IL4 exceeds about 60 nm, an excessive step difference may be formed on the surface of the hole transport region HTR disposed on the insulating layer IL, thus causing a problem in which a leakage current occurs.

The insulating layer IL may contain an insulating material. For example, the insulating layer IL may contain a photosensitizer for laser interference lithography. A laser interference lithography process is a method of patterning by irradiating an interference pattern on a member containing a photosensitizer by using two laser beams. The photosensitizer for laser interference lithography may be a photoresist. In case that the photoresist is of a negative type, a portion on which light is irradiated may remain, and in case that the photoresist is of a positive type, the portion on which light is irradiated may be removed. In case that the insulating layer IL includes a photosensitizer for laser interference lithography, the insulating layer IL may be formed through a laser interference lithography process using an argon laser as a light source. However, this is only an example, and any material may be used for the insulating layer IL without limitation as long as the material has insulating properties. The insulating layer IL may have a visible light transmittance of about 85% or more.

The hole transport region HTR is provided on the first electrode ELL The hole transport region HTR may include at least one of a hole injection layer (not illustrated), a hole transport layer (not illustrated), a buffer layer or an auxiliary light-emitting layer (not illustrated), or an electron blocking layer (not illustrated). The thickness of the hole transport region HTR may be, for example, in a range of about 50 Å to about 15,000 Å.

The hole transport region HTR may have a single layer made of a single material, a single layer made of different materials, or a multi-layered structure having layers made of different materials.

For example, the hole transport region HTR may have a single-layered structure having a hole injection layer (not illustrated) or a hole transport layer (not illustrated), or a single-layered structure made of a hole injection material and a hole transport material. The hole transport region HTR may have a single-layered structure made of different materials, or a structure made of a hole injection layer (not illustrated)/a hole transport layer (not illustrated), a hole injection layer (not illustrated)/a hole transport layer (not illustrated)/a buffer layer (not illustrated), a hole injection layer (not illustrated)/a buffer layer (not illustrated), a hole transport layer (not illustrated)/a buffer layer (not illustrated), or a hole injection layer (not illustrated)/a hole transport layer (not illustrated)/an electron blocking layer (not illustrated), which are sequentially stacked each other from the first electrode EL1, but the embodiment of the disclosure is not limited thereto.

The hole transport region HTR may be formed by using various methods such as a vacuum deposition method, a spin coating method, a casting method, a Langmuir-Blodgett (LB) method, an inkjet printing method, a laser printing method, or a laser induced thermal imaging (LITI) method.

The hole transport region HTR may include a contact portion AA1 contacting the first electrode EL1 and a non-contact portion AA2 in non-contact with the first electrode ELL The contact portion AA1 may be convex in the direction of the first electrode EL1, and the non-contact portion AA2 may be convex in the direction of the second electrode EL2.

The number of holes H transmitted to the light-emitting layer EML by the contact portion AA1 may be greater than the number of holes H transmitted to the light-emitting layer EML by the non-contact portion AA2. Accordingly, the number of excitons EX formed by the bonding of holes H and electrons E may vary depending on the location of the light-emitting layer EML, and the presence or absence of light emission may be determined according to the location of the light-emitting layer EML. For example, the presence or absence of light emission may be determined depending on whether or not the light-emitting layer EML overlaps the insulating layer IL.

The light-emitting layer EML is disposed on the hole transport region HTR. The light-emitting layer EML may have a single layer made of a single material, a single layer made of different materials, or a multi-layered structure having layers made of different materials.

The light-emitting layer EML may be a thermally-activated delayed fluorescent light-emitting layer, a hyper-fluorescent light-emitting layer, or a phosphorescent light-emitting layer. The light-emitting layer EML may contain a thermally-activated delayed fluorescent material, a hyper-fluorescent material, or a phosphorescent material which is used for triplet excitons EX to emit light. The luminous efficiency of a light-emitting element configured to emit thermally activated delayed fluorescent light, hyper-fluorescent light, or phosphorescent light may be reduced due to a triplet-triplet-annihilation (TTA) phenomenon in which interference between triplet excitons EX causes annihilation, or due to a triplet-polaron-quenching (TPQ) phenomenon in which interference between triplet excitons EX and the holes H or electrons E causes quenching. There is a problem in which a triplet-triplet-annihilation phenomenon and a triplet-polaron-quenching phenomenon increase as the density of triplet excitons EX in a portion increases.

The light-emitting layer EML may include a light-emitting portion EAA and a diffusion portion DAA. The light-emitting portion EAA may be convex in the direction of the first electrode EL1, and the diffusion portion DAA may be convex in the direction of the second electrode EL2. The light-emitting portion EAA may be a portion which overlaps the contact portion AA1 of the hole transport region HTR and through which the holes H are transmitted. The diffusion portion DAA may be a portion which overlaps the non-contact portion AA2 of the hole transport region HTR and through which the holes H are not transmitted.

The density of excitons EX in the light-emitting portion EAA may be greater than the density of excitons EX in the diffusion portion DAA. The excitons EX formed in the light-emitting portion EAA may be diffused into the diffusion portion DAA. Since some of the excitons EX generated in the light-emitting portion EAA are diffused into the diffusion portion DAA, the density of the excitons EX in the light-emitting portion EAA may be reduced. Accordingly, the triplet-triplet-annihilation phenomenon and the triplet-polaron-quenching phenomenon in the light-emitting portion EAA may be reduced. For example, in the light-emitting element ED according to an embodiment of the disclosure, since the light-emitting layer EML includes the light-emitting portion EAA and the diffusion portion DAA, the triplet-triplet-annihilation phenomenon and the triplet-polaron-quenching phenomenon may be reduced, and accordingly, there is an effect of reducing a roll-off phenomenon at a high luminance. The roll-off phenomenon refers to a phenomenon in which luminous efficiency decreases as the luminance of the light-emitting element ED increases. Hereinafter, in this specification, the meaning that the light-emitting element ED has improved roll-off characteristics may be the same as the meaning that the roll-off phenomenon is reduced.

The electron transport region ETR may have a single layer made of a single material, a single layer made of different materials, or a multi-layered structure having layers made of different materials.

For example, the electron transport region ETR may have a single-layered structure having an electron injection layer (not illustrated) or an electron transport layer (not illustrated), or a single-layered structure made of an electron injection material and an electron transport material. The electron transport region ETR may have a single-layered structure made of different materials, or a structure made of an electron transport layer (not illustrated)/an electron injection layer (not illustrated) or a hole blocking layer (not illustrated)/an electron transport layer (not illustrated)/an electron injection layer (not illustrated), which are sequentially stacked each other from the light-emitting layer EML, but the embodiment of the disclosure is not limited thereto. The thickness of the electron transport region ETR may be, for example, about 1000 Å to about 1500 Å.

The electron transport region ETR may be formed by using various methods such as a vacuum deposition method, a spin coating method, a casting method, a Langmuir-Blodgett method (LB), an inkjet printing method, a laser printing method, or a laser induced thermal imaging method (LITI).

In the electron transport region ETR, the first portions PA1 overlapping the sub-insulating layers S-IL1, S-IL2, S-IL3, and S-IL4 and the second portions PA2 non-overlapping the sub-insulating layers S-IL1, S-IL2, S-IL3, and S-IL4 may have a height difference in the thickness direction. Accordingly, the surface of the electron transport region ETR may have a curved shape. The light-emitting element ED according to an embodiment of the disclosure may have improved luminous efficiency as surface plasmon-polaritons are reduced at the interface between the electron transport region ETR and the second electrode EL2.

FIG. 8 is a schematic perspective view illustrating a portion of a light-emitting element according to a comparative embodiment of the disclosure. Referring to FIG. 8, in the light-emitting element according to the comparative embodiment of the disclosure unlike the light-emitting element according to the embodiment of the disclosure, there is a difference at least in that openings H-IL are defined in an insulating layer IL-a disposed on the first electrode ELL The opening ratio of the insulating layer IL (refer to FIG. 7) included in the light-emitting element ED (FIG. 6) according to the embodiment of the disclosure may be greater than the opening ratio of the insulating layer IL-a included in the light-emitting element according to the comparative embodiment of the disclosure. For example, in the light-emitting element ED (refer to FIG. 6) according to the embodiment of the disclosure, the opening ratio of the insulating layer IL (refer to FIG. 7) may be in a range of about 60% and about 70%, and in the light-emitting element according to the comparative embodiment of the disclosure, the opening ratio of the insulating layer IL-a may be in a range of about 30% and about 40%. Accordingly, in the light-emitting element ED (refer to FIG. 6) according to the embodiment of the disclosure, the area of the first electrode EL1 (refer to FIG. 7) exposed by the insulating layer IL (refer to FIG. 7) is wider when compared to that in the light-emitting element according to the comparative embodiment of the disclosure. Therefore, the contact area between the first electrode EL1 (refer to FIG. 7) and the hole transport region HTR (refer to FIG. 6) may be greater. Accordingly, the light-emitting element ED (refer to FIG. 6) according to the embodiment of the disclosure may have a greater current density than the light-emitting element according to the comparative embodiment of the disclosure. Since the light-emitting element ED (refer to FIG. 6) according to the embodiment of the disclosure has a larger light-emitting area than the light-emitting element according to the comparative embodiment of the disclosure, a roll-off phenomenon due to a deterioration phenomenon of the element at a high luminance may be reduced.

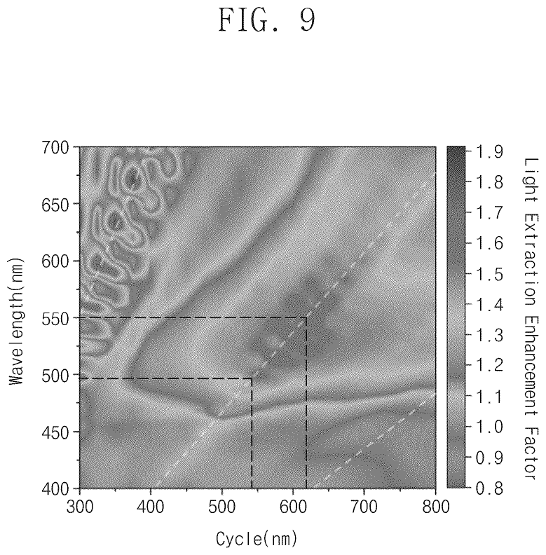

FIG. 9 is a schematic graph illustrating a simulation result of a relationship between a light-emitting wavelength, a light extraction enhancement factor, and a pitch of sub-insulating layers in a light-emitting element according to an embodiment of the disclosure. The light extraction enhancement factor shown on the right side in FIG. 9 represents a relative value of the luminous efficiency of the light-emitting element according to an embodiment of the disclosure described with reference to FIGS. 1 to 7 with respect to the luminous efficiency of the light-emitting element in which an insulating layer is not disposed between the light-emitting layer and the hole transport region. For example, it means that, as the light extraction enhancement factor increases, the light-emitting element according to an embodiment of the disclosure has excellent luminous efficiency. Referring to FIG. 9, in the light-emitting element configured to emit light having a wavelength in a range of about 450 nm to about 520 nm, it may be seen that the light extraction enhancement factor is great in case that the pitch of the sub-insulating layers is in a range of about 500 nm to about 600 nm. Through this, in case that the light-emitting element according to an embodiment of the disclosure emits light having a wavelength in a range about 450 nm to about 520 nm, it may be seen that, in case that the pitch of the bar-shaped sub-insulating layers disposed to be spaced apart from each other between the light-emitting layer and the hole transport region is adjusted to be in a range about 500 nm to about 600 nm, the light-emitting element according to the embodiment of the disclosure has excellent light efficiency.

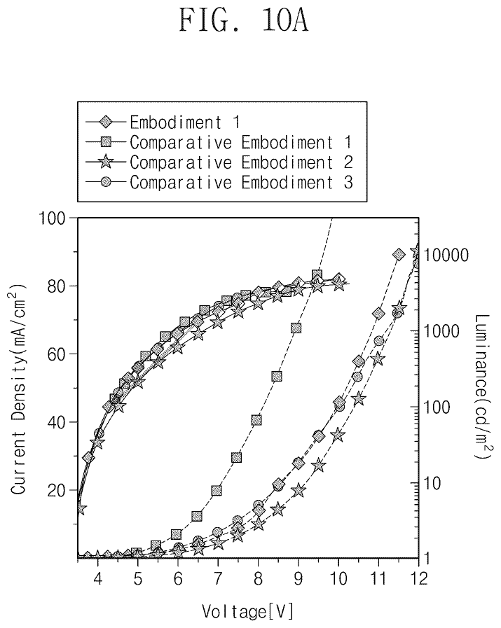

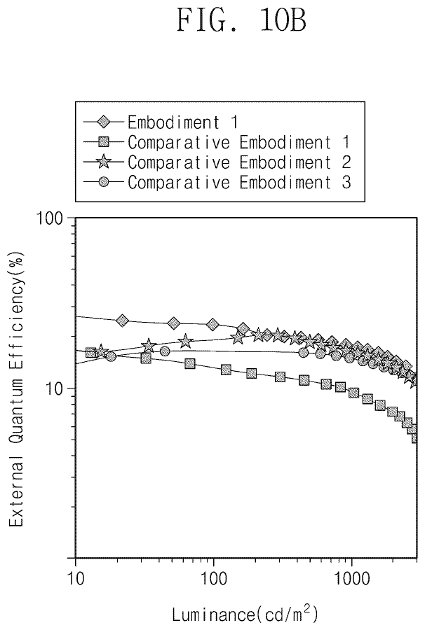

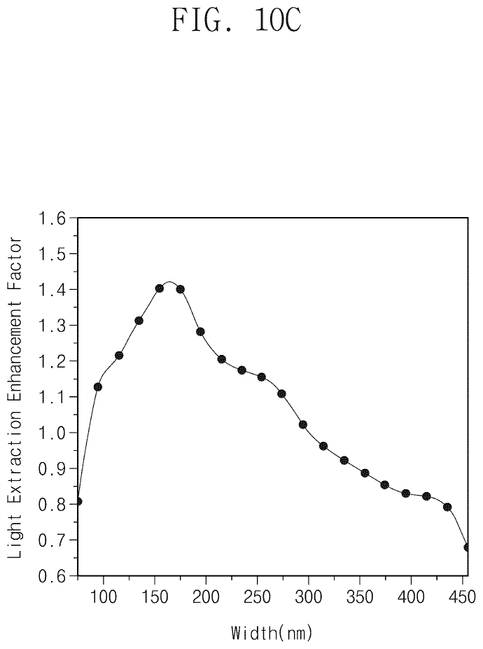

FIG. 10A is a schematic graph illustrating changes in current density and luminance in accordance with the voltages of a light-emitting element according to an embodiment of the disclosure and light-emitting elements according to comparative embodiments of the disclosure. FIG. 10B is a schematic graph illustrating changes in external quantum efficiency in accordance with the luminances of a light-emitting element according to an embodiment of the disclosure and light-emitting elements according to comparative embodiments of the disclosure. FIG. 10C is a schematic graph illustrating changes in light extraction enhancement factor in accordance with the widths of a light-emitting element according to an embodiment of the disclosure. In FIG. 10A, a solid line is a graph related to luminance, and in FIG. 10B, a dotted line is a graph related to current density. In FIGS. 10A and 10B, Comparative Embodiment 1 is a light-emitting element not including an insulating layer between the first electrode and the light-emitting layer, Comparative Embodiment 2 is a light-emitting element including an insulating layer having sub-insulating layers, each having a width of about 125 nm, Comparative Embodiment 3 is a light-emitting element including an insulating layer having sub-insulating layers, each having a width of about 400 nm, and Embodiment is a light-emitting element including an insulating layer having sub-insulating layers, each having a width of about 175 nm. FIG. 10C is a schematic graph illustrating changes in light extraction enhancement factor according to the width of each of the sub-insulating layers of the light-emitting element configured to emit blue light of about 480 nm.

Referring to FIG. 10A, when compared to the light-emitting elements according to Comparative Embodiments 1 and 3, the light-emitting element according to Embodiment 1 exhibits a high luminance under a low current density condition at the same voltage. Through this, it may be confirmed that the light-emitting element according to Embodiment 1 exhibits higher luminous efficiency than the light-emitting elements according to Comparative Embodiments 1 and 3. When compared to the light-emitting element according to Comparative Embodiment 2, the light-emitting element according to Embodiment 1 exhibits a similar luminance value under a similar current density condition at the same voltage. Through this, it may be confirmed that the light-emitting element according to Embodiment 1 exhibits luminous efficiency similar to that of the light-emitting element according to Comparative Embodiment 2.

Referring to FIG. 10B, in the light-emitting element according to Embodiment 1, the degree of decrease in luminous efficiency at a low luminance is similar to the degree of decrease in luminous efficiency at a high luminance. On the other hand, in the light-emitting element according to Comparative Embodiment 2, the degree of decrease in luminous efficiency increases at a high luminance of about 100 cd/m² or more. Through this, it may be confirmed that the light-emitting element according to Embodiment 1 has improved roll-off characteristics at a high luminance when compared to the light-emitting element according to Comparative Embodiment 2.

In the light-emitting element according to Embodiment 1 and in the light-emitting elements according to Comparative Embodiments 1 and 3, the degree of decrease in luminous efficiency at a low luminance is similar to the degree of decrease in luminous efficiency at a high luminance. Through this, it may be confirmed that, at a high luminance, the light-emitting element according to Embodiment 1 has roll-off characteristics similar in level to those of the light-emitting elements according to Comparative Embodiments 1 and 3.

It may be confirmed that the light-emitting element according to Embodiment 1 has higher external quantum efficiency than the light-emitting elements according to Comparative Embodiments 1 to 3.

Summing up the results of FIGS. 10A and 10B, the light-emitting element according to Embodiment has excellent luminous efficiency, when compared to the light-emitting elements according to Comparative Embodiments 1 to 3, and has roll-off characteristics similar in level to those of the light-emitting elements according to Comparative Embodiments 1 to 3 at a high luminance. The light-emitting element according to Embodiment and the light-emitting element according to Comparative Embodiment 2 have a same level of luminous efficiency, and the light-emitting element according to Embodiment has improved roll-off characteristics at a high luminance when compared with the light-emitting element according to Comparative Embodiment 2. Through this, in case that the width in the second direction of each of the sub-insulating layers included in the light-emitting element is adjusted to be in a range of about 150 nm to about 200 nm, it may be seen that the light-emitting element has excellent luminous efficiency and has improved roll-off characteristics at a high luminance.

Referring to FIG. 10C, in case that the width in the second of each of the sub-insulating layers included in the light-emitting element according to Embodiment is in a range of about 150 nm to about 200 nm, it can be seen that the light extraction enhancement factor is the greatest. For example, it may be seen that the light-emitting element according to Embodiment, which emits blue light having a wavelength of about 480 nm, has the best luminous efficiency in case that the width in the second direction of each of the sub-insulating layers included in the light-emitting element is in a range of about 150 nm to about 200 nm.

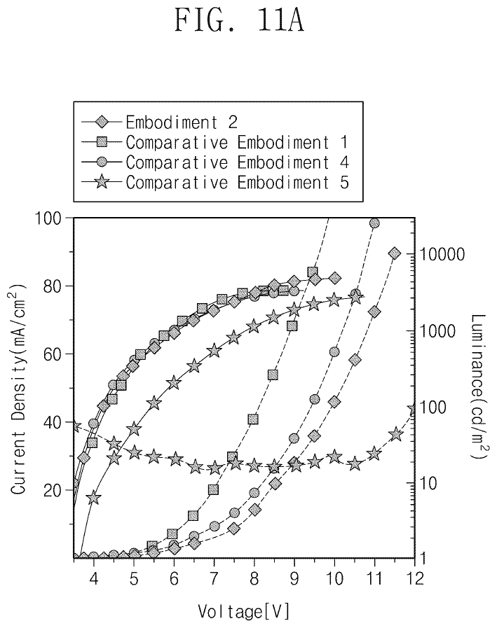

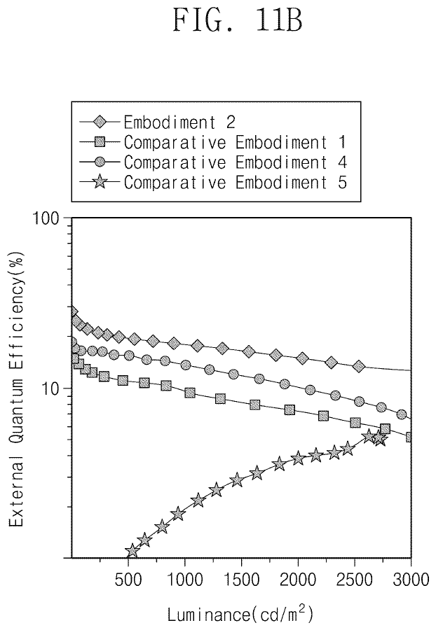

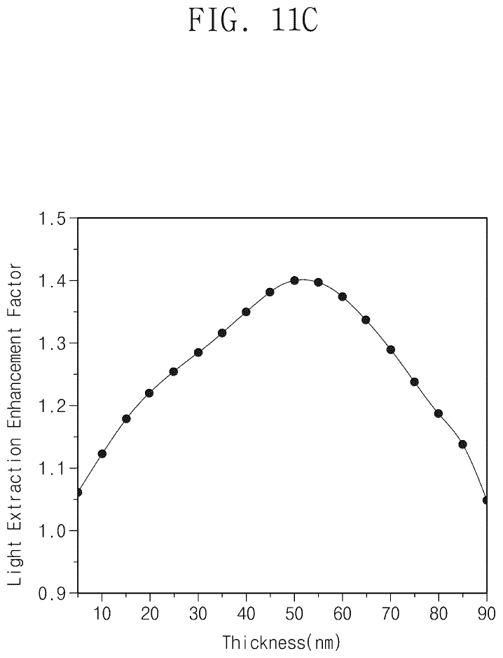

FIG. 11A is a schematic graph illustrating changes in current density and luminance in accordance with the voltages of a light-emitting element according to an embodiment of the disclosure and light-emitting elements according to comparative embodiments of the disclosure. FIG. 11B is a schematic graph illustrating changes in external quantum efficiency in accordance with the luminances of a light-emitting element according to an embodiment of the disclosure and light-emitting elements according to comparative embodiments of the disclosure. FIG. 11C is a schematic graph illustrating changes in light extraction enhancement factor in accordance with the widths of a light-emitting element according to an embodiment of the disclosure. In FIG. 11A, a solid line indicates luminance, and a dotted line indicates current density. In FIGS. 11A and 11B, Comparative Embodiment 1 is a light-emitting element not including an insulating layer between the first electrode and the light-emitting layer, Comparative Embodiment 4 is a light-emitting element including an insulating layer having sub-insulating layers, each having a thickness of about 30 nm, Comparative Embodiment 5 is a light-emitting element including an insulating layer having sub-insulating layers, each having a thickness of about 75 nm, and Embodiment 2 is a light-emitting element including an insulating layer having sub-insulating layers, each having a thickness of about 45 nm. FIG. 11C is a schematic graph illustrating changes in light extraction enhancement factor according to the thicknesses of sub-insulating layers included in the light-emitting element configured to emit blue light of about 480 nm.

Referring to FIG. 11A, it may be seen that the light-emitting element according to Embodiment 2 has higher luminous efficiency than the light-emitting elements according to Comparative Embodiments 1 and 4 and the light-emitting element according to Comparative Embodiment 5 does not operate normally. The reason why the light-emitting element according to Comparative Embodiment 5 does not operate normally is that, in case that the thickness of the sub-insulating layers is about 75 nm, the surface of organic layers including the hole transport region disposed on the sub-insulating layers has an excessive step difference, thus causing current leakage. Through this, it may be seen that the thickness of the sub-insulating layers should be adjusted to be about 45 nm.

Referring to FIG. 11B, in the light-emitting element according to Embodiment 2, it may be confirmed that the degree of decrease in luminous efficiency is small at a high luminance of about 500 cd/m² or more, when compared to the light-emitting elements according to Comparative Embodiments 1 and 4. Through this, it may be confirmed that the light-emitting element according to Embodiment 2 has improved roll-off characteristics when compared to the light-emitting elements according to Comparative Embodiments 1 and 4. Since the light-emitting element according to Comparative Embodiment 5 has a very low absolute value of luminous efficiency and shows a tendency in which the luminous efficiency increases as luminance increases, it may be confirmed that the light-emitting element is not desirably driven.

It may be confirmed that the light-emitting element according to Embodiment 2 has higher external quantum efficiency than that in Comparative Embodiments 1 and 4.

Summing up the results of FIGS. 11A and 11B, the light-emitting element according to Embodiment has excellent luminous efficiency and improved roll-off characteristics at a high luminance, when compared to the light-emitting elements according to Comparative Embodiments 1 and 4. The light-emitting element according to Comparative Embodiment 5 is not desirably driven. Through this, in case that the thickness of each of the sub-insulating layers included in the light-emitting element is adjusted to be in a range of about 30 nm to about 60 nm, it may be seen that the light-emitting element has excellent luminous efficiency and has improved roll-off characteristics at a high luminance.

Referring to FIG. 11C, in the light-emitting element according to Embodiment, in case that the thickness of each of the sub-insulating layers included in the light-emitting element is in a range of about 40 nm to about 60 nm, it may be confirmed that the light extraction enhancement factor is the greatest. For example, it may be seen that the light-emitting element according to Embodiment, which emits blue light having a wavelength of about 480 nm, has the best luminous efficiency in case that the thickness of each of the sub-insulating layers included in the light-emitting element is about in a range of 40 nm to about 60 nm.

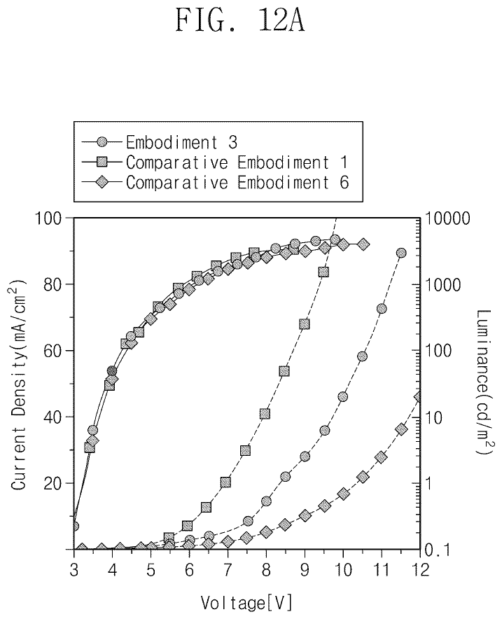

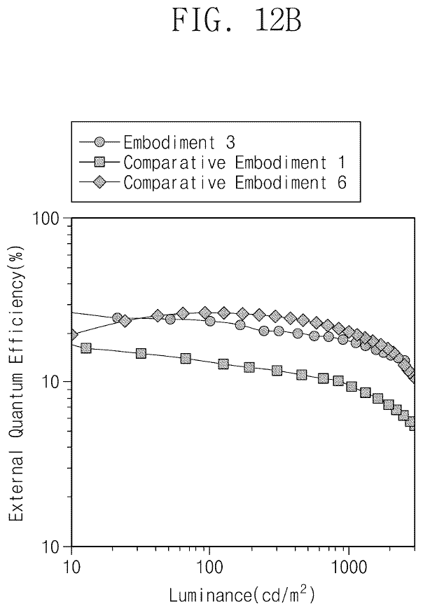

FIG. 12A is a schematic graph illustrating changes in external quantum efficiency in accordance with the luminances of a light-emitting element according to an embodiment of the disclosure and light-emitting elements according to comparative embodiments of the disclosure. FIG. 12B is a schematic graph illustrating changes in external quantum efficiency in accordance with the luminances of a light-emitting element according to an embodiment of the disclosure and light-emitting elements according to comparative embodiments of the disclosure. In FIG. 12A, a solid line is a graph related to luminance, and a dotted line is a graph related to current density. In FIGS. 12A and 12B, Comparative Embodiment 1 is a light-emitting element not including an insulating layer between the first electrode and the light-emitting layer, Comparative Embodiment 6 is a light-emitting element including an insulating layer in which holes illustrated in FIG. 7 are defined, and Embodiment 3 is a light-emitting element including an insulating layer including sub-insulating layers illustrated in FIG. 6.

Referring to FIG. 12A, it may be seen that the light-emitting element according to Embodiment 3 exhibits a similar luminance at a low current density under a same voltage condition when compared to the light-emitting element according to Comparative Embodiment 1. Through this, it may be confirmed that the light-emitting element according to Embodiment 3 has higher luminous efficiency than the light-emitting element according to Comparative Embodiment 1. It may be seen that the light-emitting element according to Embodiment 3 exhibits a relatively high luminance at a high current density under a same voltage condition when compared to the light-emitting element according to Comparative Embodiment 6. For example, it may be confirmed that the light-emitting element according to Embodiment 3 and the light-emitting element according to Comparative Embodiment 6 have a same level of luminous efficiency.

Referring to FIG. 12B, in the light-emitting element according to Embodiment 3, it may be confirmed that the rate of change in external quantum efficiency according to a change in luminance at a low luminance is similar to the rate of change in external quantum efficiency according to a change in luminance at a high luminance. On the other hand, in the light-emitting elements according to Comparative Embodiments 1 and 6, it may be confirmed that the rate of change in external quantum efficiency according to a change in luminance increases as the luminance increases. Through this, it may be seen that a roll-off phenomenon in the light-emitting element according to Embodiment 3 is reduced at a high luminance when compared to the light-emitting elements according to Comparative Embodiments 1 and 6. For example, it may be seen that, in case that sub-insulating layers disposed to be spaced apart from each other between the light-emitting layer and the hole transport region are included, a roll-off phenomenon is reduced at a high luminance, compared to when an insulating layer is not included between the light-emitting layer and the hole transport region and when insulating layers in which holes are defined are included between the light-emitting layer and the hole transport region.

Referring to FIGS. 12A and 12B, it may be seen that the light-emitting element according to Embodiment 3 has excellent luminous efficiency and improved roll-off characteristics at a high luminance when compared to the light-emitting element according to Comparative Embodiment 1. It can be seen that the light-emitting element according to Embodiment 3 and the light-emitting element according to Comparative Embodiment 6 have a same level of luminous efficiency, and the light-emitting element according to Embodiment 3 has improved roll-off characteristics at a high luminance when compared with the light-emitting element according to Comparative Embodiment 6.

The light-emitting element according to an embodiment of the disclosure includes an insulating layer including sub-insulating layers disposed between the light-emitting layer and the hole transport region and having a bar shape extending in the first direction so that a contact area between the hole transport region and the first electrode may be adjusted and a diffraction grating may be formed on the surface of the electron transport region disposed on the insulating layer. Accordingly, the light-emitting element according to an embodiment of the disclosure may have improved roll-off characteristics at a high luminance and excellent luminous efficiency. The display device including the light-emitting element according to an embodiment of the disclosure may have excellent luminous efficiency.

Since the light-emitting element according to an embodiment of the disclosure includes an insulating layer including bar-shaped sub-insulating layers disposed to be spaced apart from each other between the light-emitting layer and the hole transport region, the light-emitting element may have high luminous efficiency and a roll-off phenomenon may be suppressed at a high luminance.

Since the display device according to an embodiment of the disclosure includes a light-emitting element including an insulating layer including bar-shaped sub-insulating layers disposed to be spaced apart from each other between the light-emitting layer and the hole transport region, the display device may have high luminous efficiency and a roll-off phenomenon may be suppressed at a high luminance.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A light-emitting element comprising:
a first electrode;
an insulating layer comprising a plurality of sub-insulating layers disposed on the first electrode, spaced apart from each other by a distance in a first direction, and having a bar shape extending in a second direction substantially perpendicular to the first direction;
a hole transport region disposed on the insulating layer and comprising:
a contact portion in contact with the first electrode; and
a non-contact portion not contacting the first electrode;
a light-emitting layer disposed on the hole transport region and comprising:
a light-emitting portion overlapping the contact portion in a plan view; and
a diffusion portion overlapping the non-contact portion in a plan view;
an electron transport region disposed on the light-emitting layer; and
a second electrode disposed on the electron transport region.

2. The light-emitting element of claim 1, wherein the light-emitting layer emits light in a range of about 450 nm to about 520 nm.

3. The light-emitting element of claim 1, wherein a thickness of each of the plurality of sub-insulating layers is in a range of about 30 nm to about 60 nm.

4. The light-emitting element of claim 1, wherein a width in the first direction of each of the plurality of sub-insulating layers is in a range of about 150 nm to about 200 nm.

5. The light-emitting element of claim 1, wherein the electron transport region comprises:
a plurality of first portions overlapping the plurality of sub-insulating layers in a plan view; and
a plurality of second portions non-overlapping the plurality of sub-insulating layers in a plan view, wherein:
each of the plurality of first portions has a convex shape in a direction of the second electrode; and
each of the plurality of second portions has a convex shape in a direction of the first electrode.

6. The light-emitting element of claim 1, wherein a sum of a separation distance between adjacent sub-insulating layers of the plurality of sub-insulating layers and a width in the first direction of one of the adjacent sub-insulating layers is in a range of about 500 nm to about 600 nm.

7. The light-emitting element of claim 1, each of the plurality of sub-insulating layers comprises a photosensitizer for laser interference lithography.

8. The light-emitting element of claim 1, wherein the insulating layer has a visible light transmittance of about 85% or more.

9. The light-emitting element of claim 1, wherein the light-emitting layer is a thermally-activated delayed fluorescent light-emitting layer, a hyper-fluorescent light-emitting layer, or a phosphorescent light-emitting layer.

10. The light-emitting element of claim 1, wherein:
excitons are formed in the light-emitting layer; and
a density of the excitons in the light-emitting portion is greater than a density of the excitons in the diffusion portion.

11. A display device comprising:
first to third light-emitting regions;
a circuit layer disposed on a base substrate; and
a light-emitting layer comprising:
a pixel defining film disposed on the circuit layer and having an opening; and
first to third light-emitting elements,
wherein each of the first to third light-emitting elements comprises:
a first electrode exposed by the pixel defining film;
an insulating layer comprising a plurality of sub-insulating layers disposed on the first electrode, spaced apart from each other by a distance in a first direction in the opening, and having a bar shape extending in a second direction substantially perpendicular to the first direction in a plan view;
a hole transport region disposed on the insulating layer and comprising:
a contact portion in contact with the first electrode; and
a non-contact portion not contacting the first electrode;
a light-emitting layer disposed on the hole transport region and divided by the pixel defining film;
an electron transport region disposed on the light-emitting layer; and
a second electrode disposed on the electron transport region.

12. The display device of claim 11, wherein the light-emitting layer is a thermally activated delayed fluorescent light-emitting layer, a hyper-fluorescent light-emitting layer, or a phosphorescent light-emitting layer.

13. The display device of claim 11, wherein
the light-emitting layer comprises:
a first light-emitting layer disposed to correspond to the first light-emitting region;
a second light-emitting layer disposed to correspond to the second light-emitting region; and
a third light-emitting layer disposed to correspond to the third light-emitting region, and
the first to third light-emitting layers respectively emit light of different wavelength ranges.

14. The display device of claim 11, wherein
the electron transport region comprises:
a plurality of first portions overlapping the plurality of sub-insulating layers in a plan view; and
a plurality of second portions non-overlapping the plurality of sub-insulating layers in a plan view, and
each of the plurality of first portions has a convex shape in a direction of the second electrode; and
each of the plurality of second portions has a convex shape in a direction of the first electrode.

15. The display device of claim 11, wherein, in at least one of the first to third light-emitting elements, a thickness of each of the plurality of sub-insulating layers is in a range of about 30 nm to about 60 nm.

16. The display device of claim 11, wherein a sum of a separation distance between adjacent sub-insulating layers of the plurality of sub-insulating layers and a width in the first direction of one of the adjacent sub-insulating layers is in a range of about 500 nm to about 600 nm.

17. The display device of claim 11, wherein, in at least one of the first to third light-emitting elements, a width in the first direction of each of the plurality of sub-insulating layers is in a range of about 150 nm to about 200 nm.

18. The display device of claim 11, wherein the insulating layer has a visible light transmittance of about 85% or more.

19. The display device of claim 11, wherein each of the plurality of sub-insulating layer comprises a photosensitizer for laser interference lithography.

20. The display device of claim 11, wherein:
the light-emitting layer comprises:
a light-emitting portion overlapping the contact portion in a plan view; and
a diffusion portion overlapping the non-contact portion in a plan view;
excitons are formed in the light-emitting layer; and
a density of the excitons in the light-emitting portion is greater than a density of the excitons in the diffusion portion.
